(19) United States
(12) Patent Application Publication
(10) Pub. No.: US 2026/0143940 A1
(43) Pub. Date: May 21, 2026

(54) DISPLAY PANEL AND DISPLAY DEVICE

(71) Applicant: BOE Technology Group Co., Ltd., Beijing (CN)

(72) Inventors: Wenxiu ZHU, Beijing (CN); Lujiang HUANGFU, Beijing (CN)

(21) Appl. No.: 18/705,859

(22) PCT Filed: Jul. 31, 2023
(86) PCT No.: PCT/CN2023/110369

§ 371 Date: Apr. 29, 2024

(51) Int. Cl. H10K 59/35

(52) U.S. Cl. CPC H10K 59/353

(57) ABSTRACT

The present disclosure provides a display panel and a display device. The display panel includes pixels arranged in an array, a row direction of the array being a first direction, each of the pixels including a first sub-pixel, a second sub-pixel and a third sub-pixel, and the first sub-pixel, the second sub-pixel and the third sub-pixel being arranged in intervals along a second direction in sequence, where the first direction and the second direction have an angle therebetween, the angle being non-zero; a first pixel among the pixels and a second pixel among the pixels and neighboring the first pixel in the first direction or the second direction share one or two sub-pixels to form a multiplexed pixel, and an arrangement of the first sub-pixel, the second sub-pixel and the third sub-pixel of the multiplexed pixel is different from that of the second pixel.

### CROSS REFERENCE TO RELATED APPLICATIONS

The present application is a U.S. National Stage of International Application No. PCT/CN2023/110369 filed on Jul. 31, 2023, the content of which is incorporated herein by reference in its entirety.

### TECHNICAL FIELD

The present disclosure relates to the field of display technology, and in particular to a display panel and a display device.

### BACKGROUND

With the development of the economy, a display panel is more and more widely used in people's lives. The display panel mainly includes a light emitting unit. The light emitting unit includes two electrodes disposed opposite to each other and a light emitting layer disposed between the two electrodes. The two electrodes are electrically connected to a power source to supply power to the light emitting layer. However, the existing display panel has a low resolution.

### SUMMARY

The purpose of the present disclosure is to provide a display panel and a display device capable of achieving a high resolution display effect.

According to an aspect of the present disclosure, there is provided a display panel including:
pixels arranged in an array, a row direction of the array being a first direction, each of the pixels including a first sub-pixel, a second sub-pixel and a third sub-pixel, the first sub-pixel, the second sub-pixel and the third sub-pixel being arranged in intervals along a second direction in sequence, where the first direction and the second direction have an angle therebetween, the angle being non-zero;
where a first pixel among the pixels and a second pixel among the pixels and neighboring the first pixel in the first direction or the second direction share one or two sub-pixels to form a multiplexed pixel, and where an arrangement of the first sub-pixel, the second sub-pixel, and the third sub-pixel of the multiplexed pixel is different from an arrangement of the first sub-pixel, the second sub-pixel, and the third sub-pixel of the second pixel.

In some embodiments, the first sub-pixel, the second sub-pixel and the third sub-pixel of the multiplexed pixel and the first sub-pixel, the second sub-pixel and the third sub-pixel of the first pixel are arranged in intervals in a row along the second direction, and an arrangement order of the first sub-pixel, the second sub-pixel and the third sub-pixel of the multiplexed pixel is different from an arrangement order of the first sub-pixel, second sub-pixel and third sub-pixel of the first pixel.

In some embodiments, the first sub-pixel, the second sub-pixel and the third sub-pixel of the multiplexed pixel are distributed in at least two rows in the first direction, and the first sub-pixel, the second sub-pixel and the third sub-pixel of the first pixel are distributed in one row in the first direction.

In some embodiments, the first sub-pixel, the second sub-pixel and the third sub-pixel of the first pixel are distributed in a N^{th} row in the first direction, one or more shared sub-pixels of the second-type multiplexed pixel are distributed in the N^{th} row in the first direction, the first sub-pixel, the second sub-pixel and the third sub-pixel of the multiplexed pixel are distributed in at least the N^{th} row and a (N−1)^{th} row in the first direction or the first sub-pixel, the second sub-pixel and the third sub-pixel of the multiplexed pixel are distributed in at least the N^{th} row and a (N+1)^{th} row in the first direction.

In some embodiments, the first sub-pixel, the second sub-pixel and the third sub-pixel of the multiplexed pixel are distributed in three rows in the first direction, respectively.

In some embodiments, at least one or two sub-pixels among the sub-pixels of the pixels are shared by four pixels among the pixels, with two pixels of the four pixels located in a row where the shared sub-pixels are located, and the other two pixels located in two rows on both sides of the shared sub-pixels, respectively.

In some embodiments, where one sub-pixel is shared by the first pixel and the second adjacent pixel, the one sub-pixel is a first sub-pixel, a second sub-pixel or a third sub-pixel.

In some embodiments, where two sub-pixels are shared by the first the pixel and the second adjacent pixel, the two sub-pixels are a first sub-pixel and a second sub-pixel, or a second sub-pixel and a third sub-pixel.

In some embodiments, the first sub-pixel, the second sub-pixel and the third sub-pixel are a red sub-pixel, a green sub-pixel and a blue sub-pixel, respectively.

In some embodiments, an area ratio of the second sub-pixel to the first sub-pixel is greater than 1 and less than or equal to 3, and an area ratio of the third sub-pixel to the first sub-pixel is greater than 1.2 and less than or equal to 4.

In some embodiments, the first sub-pixel, the second sub-pixel and the third sub-pixel are rectangular, elliptical or polygonal.

In some embodiments, the first sub-pixel, the second sub-pixel and the third sub-pixel are rectangular, and one of the first sub-pixel, second sub-pixel and third sub-pixel has long edges D1, and the other two sub-pixels have long edges D2, D3, both D2 and D3 being between 0.8 D1 to 1.2 D1.

In some embodiments, the long edges of the first sub-pixel, the second sub-pixel and the third sub-pixel are equal.

In some embodiments, the long edges of the first sub-pixel, the second sub-pixel and the third sub-pixel are parallel to the first direction.

In some embodiments, short edges of the first sub-pixel, the second sub-pixel and the third sub-pixel are parallel to the second direction.

In some embodiments, the angle between the first direction and the second direction is an acute or right angle; and

the display panel has scanning lines and data lines arranged in a crisscrossed manner, and the first direction and a direction in which the scanning lines extends have an angle therebetween, the angle being an acute angle.

According to an aspect of the present disclosure, there is provided a display device including the display panel.

In the display panel and the display device of the present disclosure, in at least one of the first direction and the second direction, one or two sub-pixels are shared between at least one pixel and at least one adjacent pixel to form at least one multiplexed pixel so as to facilitate increasing the resolution of the display panel, thereby improving the display effect of the display panel.

### BRIEF DESCRIPTION OF DRAWINGS

FIG. 1 is a schematic diagram of a structure of a display device provided by an embodiment of the present application.

FIG. 2 is a schematic diagram of a sub-pixel arrangement structure of a display panel provided by an embodiment of the present application.

FIG. 3 is a schematic diagram of a sub-pixel arrangement structure of another display panel provided by an embodiment of the present application.

FIG. 4 is a schematic diagram of a sub-pixel arrangement structure of another display panel provided by an embodiment of the present application.

FIG. 5 is a schematic diagram of a sub-pixel arrangement structure of another display panel provided by an embodiment of the present application.

FIG. 6 is a schematic diagram of a sub-pixel arrangement structure of another display panel provided by an embodiment of the present application.

FIG. 7 is a schematic diagram of a sub-pixel arrangement structure of another display panel provided by an embodiment of the present application.

FIG. 8 is a schematic diagram of a sub-pixel arrangement structure of another display panel provided by an embodiment of the present application.

FIG. 9 is a schematic diagram of a sub-pixel arrangement structure of another display panel provided by an embodiment of the present application.

FIG. 10 is a schematic diagram of a sub-pixel arrangement structure of another display panel provided by an embodiment of the present application.

FIG. 11 is a schematic diagram of a sub-pixel arrangement structure of another display panel provided by an embodiment of the present application.

FIG. 12 is a schematic diagram of a sub-pixel arrangement structure of another display panel provided by an embodiment of the present application.

FIG. 13 is a schematic diagram of a sub-pixel arrangement structure of another display panel provided by an embodiment of the present application.

FIG. 14 is a schematic diagram of a sub-pixel arrangement structure of another display panel provided by an embodiment of the present application.

FIG. 15 is a schematic diagram of a sub-pixel arrangement structure of another display panel provided by an embodiment of the present application.

FIG. 16 is a schematic diagram of a sub-pixel arrangement structure of another display panel provided by an embodiment of the present application.

FIG. 17 is a schematic diagram of a sub-pixel arrangement structure of another display panel provided by an embodiment of the present application.

FIG. 18 is a schematic diagram of a sub-pixel arrangement structure of another display panel provided by an embodiment of the present application.

FIG. 19 is a schematic diagram of a sub-pixel arrangement structure of another display panel provided by an embodiment of the present application.

FIG. 20 is a schematic diagram of a sub-pixel arrangement structure of another display panel provided by an embodiment of the present application.

FIG. 21 is a schematic diagram of a sub-pixel arrangement structure of another display panel provided by an embodiment of the present application.

FIG. 22 is a schematic diagram of a sub-pixel arrangement structure of another display panel provided by an embodiment of the present application.

### DETAILED DESCRIPTION

Embodiments will be described herein in detail, examples of which are represented in the accompanying drawings. When the following descriptions involve the drawings, like numerals in different drawings represent like or similar elements unless stated otherwise. The embodiments described in the following do not represent all embodiments consistent with the present disclosure. Rather, they are merely device examples consistent with some aspects of the present disclosure as detailed in the appended claims.

The term used in the present disclosure is for the purpose of describing particular examples only and is not intended to limit the present disclosure. Unless otherwise defined, the technical or scientific terms used in the present disclosure shall have the usual meanings understood by those of ordinary skill in the field to which the present disclosure belongs. The terms “first,” “second,” and the like as used in the specification and the claims of the present disclosure do not indicate any order, number, or importance, but are used only to distinguish between different components. Similarly, the terms “a” or “an” and the like do not mean a quantity limit, but mean that there is at least one. The terms “a plurality of” or “several” indicate two and more. Unless otherwise indicated, terms such as “front”, “rear”, “lower” and/or “upper” are used for the purpose of illustration only and are not limited to a single location or spatial orientation. Similar terms such as “include” or “comprise” mean that the elements or objects before “include” or “comprise” cover the elements or objects listed after “include” or “comprise” and their equivalents, and other elements or objects are not excluded. “Connected to” or “connected with” and similar terms are not limited to physical or mechanical connections, and can include electrical connections, whether direct or indirect. Terms determined by “a”, “the” and “said” in their singular forms in the specification and the appended claims of the present disclosure are also intended to include plurality, unless clearly indicated otherwise in the context. It should also be understood that the term “and/or” as used herein refers to and includes any and all possible combinations of one or more of the associated listed items.

Embodiments of the present application provide a display panel and a display device. The display panel includes a plurality of pixels arranged in an array, a row direction of the array being a first direction, each of the pixels including a first sub-pixel, a second sub-pixel and a third sub-pixel, the first sub-pixel, and the second sub-pixel and the third sub-pixel being arranged in intervals along a second direction in sequence, where the first direction and the second direction have an angle therebetween; in at least one of the first direction and the second direction, one or two sub-pixels are shared between at least one of the pixels and at least one adjacent pixel to form at least one multiplexed pixel, and an arrangement of the first sub-pixel, the second sub-pixel and the third sub-pixel of the multiplexed pixel is different from an arrangement of the first sub-pixel, the second sub-pixel and the third sub-pixel of the at least one adjacent pixel. The above-described display panel, in at least one of the first direction and the second direction, is rendered by sharing one or two sub-pixels between at least one pixel and at least one adjacent pixel to form at least one multiplexed pixel so as to facilitate increasing the resolution of the display panel, thereby improving the display effect of the display panel.

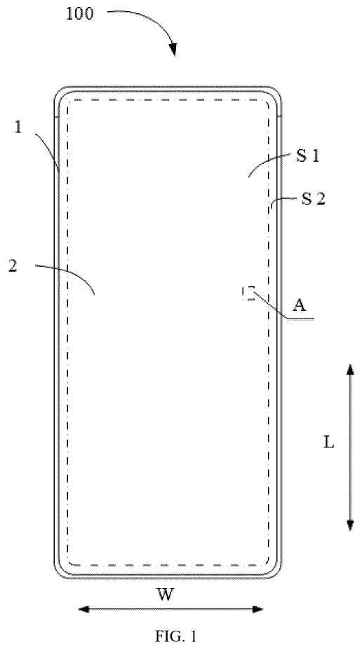

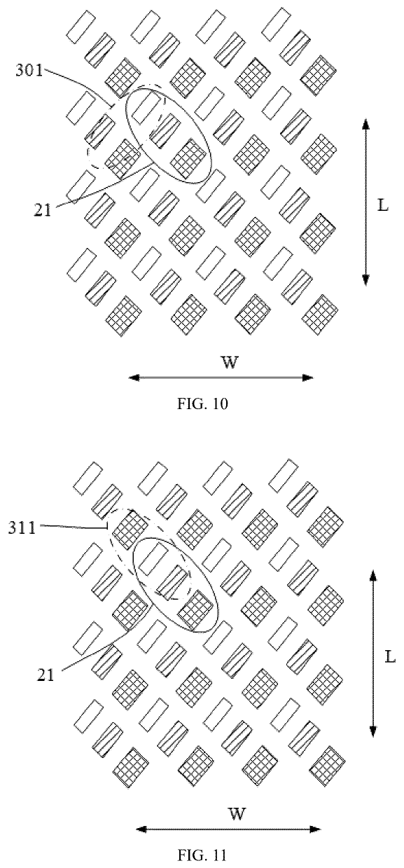

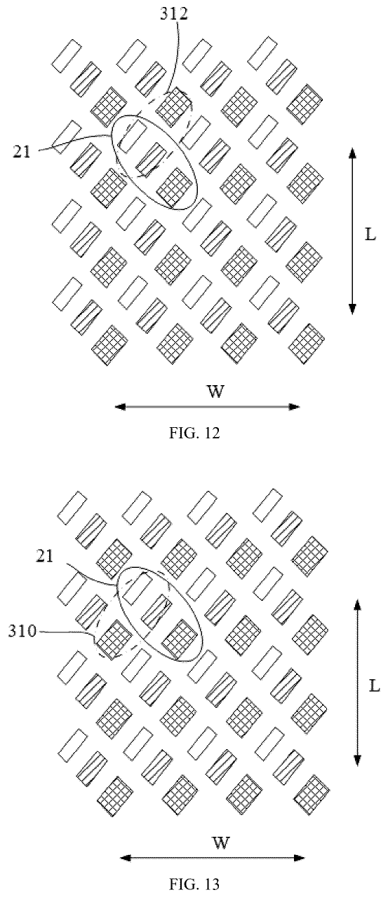

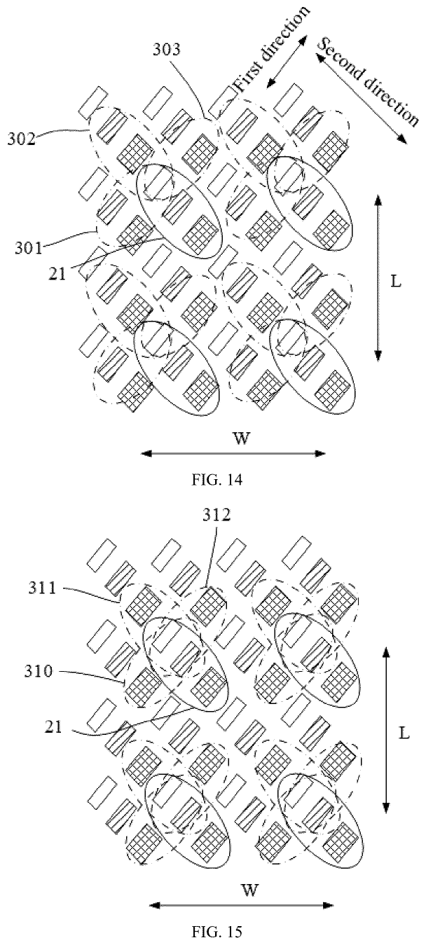

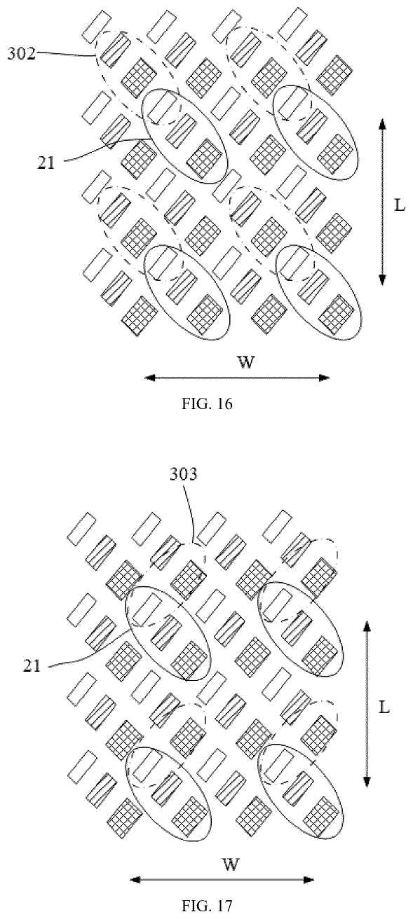

The display panel and the display device provided by embodiments of the present application are described in detail below in conjunction with FIGS. 1 to 22.

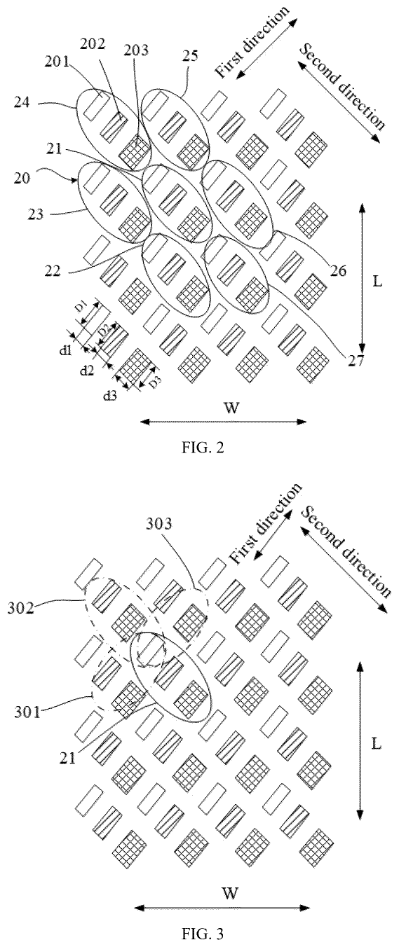

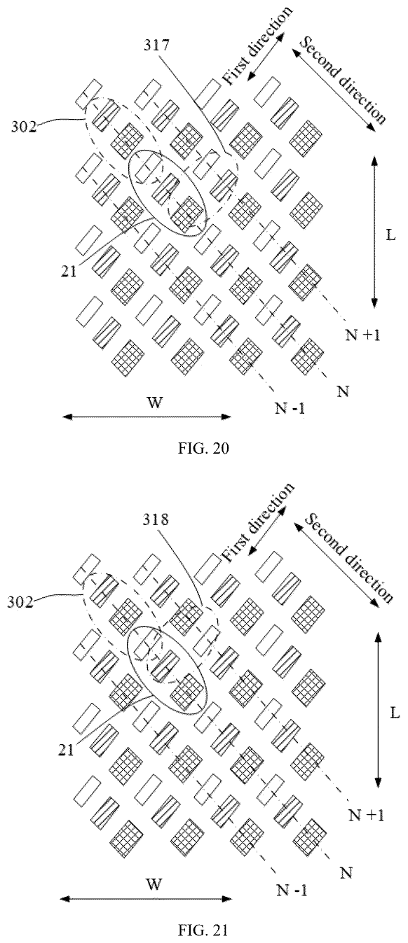

First, with reference to FIG. 1, and in conjunction with FIG. 2, FIG. 3, FIG. 19, and FIG. 20, where necessary, FIG. 1 is a schematic diagram of a structure of a display device provided by an embodiment of the present application. As shown in FIG. 1, the display device 100 includes a device body 1 and a display panel 2 disposed on top of the device body.

The display device 100 described herein may be an electronic device having a display panel such as a cellular phone, a tablet computer, a television, and the like. The display panel 2 described herein may be an organic light emitting diode (OLED) display panel.

The display device has a width direction W and a length direction L. In some embodiments, the width direction W and the length direction L are perpendicular to each other.

The display panel 2 may include a substrate and a driving circuit layer. The substrate may be a rigid substrate. The rigid substrate may include a glass substrate, a polymethyl methacrylate (PMMA) substrate, or the like. In other embodiments, the substrate may be a flexible substrate. The flexible substrate may include a polyethylene terephthalate (PET) substrate, a polyethylene naphthalate two formic acid glycol ester (PEN) substrate, or a polyimide (PI) substrate.

The driving circuit layer may be disposed on the substrate. The driving circuit layer may include a plurality of driving transistors. The driving transistors may be thin-film transistors, but the embodiments of the present disclosure are not limited thereto. The thin-film transistors may be top-gate thin-film transistors; in other embodiments, the thin-film transistors may also be bottom-gate thin-film transistors. In the case where the thin-film transistors are top-gate thin-film transistors, for example, the driving circuit layer may include an active layer, a gate insulation layer, a gate electrode, an interlayer insulation layer, a source electrode, and a drain electrode. The active layer may be disposed on the substrate. The gate insulation layer may be disposed on the substrate and cover the active layer. The gate electrode may be disposed on a side of the gate insulation layer away from the substrate. The interlayer insulation layer may be disposed on the gate insulation layer and cover the gate electrode. The source electrode and the drain electrode may be disposed on the interlayer insulation layer and connected to the active layer through vias passing through the interlayer insulation layer and the gate insulation layer. The display panel of the embodiments of the present disclosure may further include a planarization layer and a pixel definition layer. The planarization layer may be disposed on a surface of the driving circuit layer facing away from the substrate and cover the source electrode and the drain electrode of the above-described driving transistors. The pixel definition layer may be disposed on the above-described planarization layer. The pixel definition layer may be provided with pixel openings. The number of the pixel openings is plural. The pixel openings are used to vaporize light emitting material to form sub-pixels.

The driving circuit layer of the display panel has signal lines such as scanning lines and data lines arranged in a crisscrossed manner so as to provide corresponding signals to structures such as the thin-film transistors. The display device further includes a control circuit board (which may also be referred to as a motherboard) having a timing control module in the control circuit board. The timing control module is connected to the scanning lines and data lines, and is capable of providing, for signal lines such as scanning lines and data lines, required signals to drive each sub-pixel to emit light.

The display panel 2 has a display area S1 and non-display areas S2 disposed on at least one side of the display area S1. The display panel 2 includes a plurality of pixels (which may also be referred to as pixel units) 20 disposed in the display area S1. The plurality of pixel units 20 are arranged in an array.

In the present application, an arrangement of the plurality of pixels is an O-Stripe pixel arrangement.

A row direction of the array is a first direction, and each of the pixels includes a first sub-pixel 201, a second sub-pixel 202 and a third sub-pixel 203, the first sub-pixel 201, the second sub-pixel 202 and the third sub-pixel 203 being arranged in intervals along a second direction in sequence, where the first direction and the second direction have an angle therebetween.

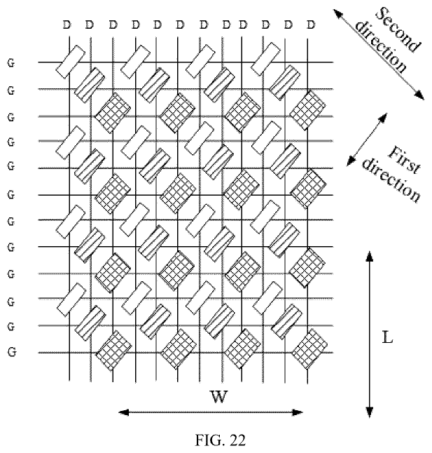

In conjunction with FIG. 22, the display panel 2 has a plurality of scanning lines G (i.e., GOA lines) and a plurality of data lines D (i.e., data Source lines) arranged in a crisscrossed manner. The scanning lines G extend in a width direction W, and the data lines D extend in a length direction L. In the width direction W and the length direction L, all pixels are also arranged in an array. Each scanning line G corresponds to a row of sub-pixels arranged along the width direction W, and each data line D corresponds to a column of sub-pixels arranged along the length direction L.

In at least one of the first direction and the second direction, a pixel 21 has an adjacent pixel 22, pixel 23, pixel 24, pixel 25, pixel 26, and pixel 27. Herein, take the pixel 21 as an example, the pixel 21 may share, with at least one of the adjacent pixel 22, pixel 23, pixel 24, pixel 25, pixel 26, and pixel 27, one or two sub-pixels to form at least one multiplexed pixel different from the pixel 21, pixel 22, pixel 23, pixel 24, pixel 25, pixel 26 and pixel 27 of the display panel in an area where the pixel 21, pixel 22, pixel 23, pixel 24, pixel 25, pixel 26 and pixel 27 are located, such as the multiplexed pixels 301, 302, 303 in FIG. 3. And, an arrangement of the first sub-pixel 201, the second sub-pixel 202 and the third sub-pixel 203 of the formed multiplexed pixels is different from an arrangement of the first sub-pixel 201, the second sub-pixel 202 and the third sub-pixel 203 of the at least one adjacent pixel.

The row direction of the array is the first direction, and it is understood that pixels of each row may be set in alignment in the first direction, that is, each row formed by pixels may be arranged parallel to the first direction. In some embodiments, an arrangement of the pixels may be based on a specific shape of the display panel, for example, the shape of the display panel is generally a rectangle and the shape of the display area is also a rectangle. In this way, each pixel may also be arranged in accordance with a predetermined rule where the pixels of the two adjacent columns are staggered by a predetermined size in the first direction to improve pixel arrangement rate.

In some embodiments, the formed multiplexed pixels include a first-type multiplexed pixel. The first sub-pixel 201, the second sub-pixel 202 and the third sub-pixel 203 of this first-type multiplexed pixel and the first sub-pixel 201, the second sub-pixel 202 and the third sub-pixel 203 of the at least one pixel are arranged in intervals in a row along the second direction, and an arrangement order of the first sub-pixel 201, the second sub-pixel 202 and the third sub-pixel 203 of the first-type multiplexed pixel is different from an arrangement order of the first sub-pixel 201, second sub-pixel 202 and third sub-pixel 203 of one pixel of the at least one pixel.

For example, a multiplexed pixel 302 shown in FIG. 3 is a first-type multiplexed pixel. The first sub-pixel 201, the second sub-pixel 202 and the third sub-pixel 203 of this multiplexed pixel 302 and the first sub-pixel 201, the second sub-pixel 202 and the third sub-pixel 203 of the adjacent pixel 21 are all arranged in intervals along the second direction, but arrangement orders of the sub-pixels of these two pixels are different. Along the second direction and in a direction from the upper left toward the lower right in the FIG. 3, the arrangement order of the sub-pixels of the multiplexed pixel 302 is the second sub-pixel 202, the third sub-pixel 203 and the first sub-pixel 201, whereas the arrangement order of the sub-pixels of the pixel 21 in this direction is the first sub-pixel 201, the second sub-pixel 202 and the third sub-pixel 203.

In some embodiments, at least one of the multiplexed pixels includes a second-type multiplexed pixel, the first sub-pixel 201, the second sub-pixel 202 and the third sub-pixel 203 of the second-type multiplexed pixel being distributed in at least two rows in the first direction, and the first sub-pixel 201, the second sub-pixel 202 and the third sub-pixel 203 of the at least one pixel being distributed in one row in the first direction.

If the first sub-pixel, the second sub-pixel and the third sub-pixel of the at least one pixel are distributed in a N^{th} row in the first direction, shared sub-pixel(s) of the second-type multiplexed pixel are distributed in the N^{th} row in the first direction, the first sub-pixel, the second sub-pixel and the third sub-pixel of the second-type multiplexed pixel are distributed in at least the N^{th} row and (N−1)^{th} row in the first direction or the first sub-pixel, the second sub-pixel and the third sub-pixel of the second-type multiplexed pixel are distributed in at least the N^{th} row and (N+1)^{th} row in the first direction.

For example, multiplexed pixels 301 and 303 shown in FIG. 3 are second-type multiplexed pixels. The first sub-pixel 201, the second sub-pixel 202 and the third sub-pixel 203 included in this multiplexed pixel 301 are distributed in two rows in the first direction. The first sub-pixel 201, the second sub-pixel 202 and the third sub-pixel 203 included in the multiplexed pixel 303 are distributed in two rows in the first direction. And the first sub-pixel 201, the second sub-pixel 202 and the third sub-pixel 203 included in the pixel 21 are distributed in the same row.

Further in conjunction with FIG. 3, if the first sub-pixel 201, the second sub-pixel 202 and the third sub-pixel 203 of the pixel 21 are distributed in the Nth row in the first direction, where a row immediately adjacent to the Nth row and towards the lower left along the first direction is the (N−1)^{th} row, and a row immediately adjacent to the Nth row and towards the upper right along the first direction is the (N+1)^{th} row. The shared sub-pixel(s) 201 of the second-type multiplexed pixel is distributed in the Nth row in the first direction, and the first sub-pixel 201, the second sub-pixel 202, and the third sub-pixel 203 of the multiplexed pixel 301 are distributed in the N^{th} row and (N−1)^{th} row in the first direction. The first sub-pixel, the second sub-pixel and the third sub-pixel of the multiplexed pixel 303 are distributed in at least the N^{th} row and (N+1)^{th} row in the first direction.

In addition, in some other embodiments, the second-type multiplexed pixel may also be configured to cross three rows in the first direction, for example, three sub-pixels of a multiplexed pixel 316 shown in FIG. 19 are arranged in the N^{th}, (N−1)^{th} and (N+1)^{th} rows, respectively, in the first direction.

In some embodiments, among sub-pixels of the plurality of pixels arranged in the array, at least one or two sub-pixels are shared by four pixels, with two pixels of the four pixels located in a row where the shared sub-pixel(s) are located, and the other two pixels located in two rows on both sides of the row where the shared sub-pixel(s) are located, respectively.

For example, the first sub-pixel 201 of the pixel 21 shown in FIG. 3 is shared by the pixel 21 and the multiplexed pixels 301, 302, 303. The multiplexed pixel 302 is located in the same row as the pixel 21, and the multiplexed pixels 301 and 303 are located in two rows adjacent to the shared first sub-pixel 201, respectively.

It should be noted that for cases that one sub-pixel is shared, any one of the first sub-pixel 201, the second sub-pixel 202 and the third sub-pixel 203 of the pixel 21 may be shared herein. For cases that two sub-pixels are shared, the first sub-pixel 201 and the second sub-pixel 202, or the second sub-pixel 202 and the third sub-pixel 203, may be shared herein.

It will be appreciated that the pixel 21 may share a sub-pixel with one or two pixels adjacent to the pixel 21 to form multiplexed pixels. Or, the pixel 21 may share two sub-pixels with one pixel adjacent to the pixel 21 to form a multiplexed pixel.

It will be appreciated that herein the first direction and the width direction W have an angle therebetween, i.e., the first direction and the direction in which the scanning lines G extend have an angle therebetween, the angle being an acute angle. The first direction and the length direction L also have an angle therebetween. And, herein the second direction and the width direction W have an angle therebetween. The second direction and the length direction L also have an angle therebetween.

The above-described display panel 2, in at least one of the first direction and the second direction, is rendered by setting the pixel 21 to share one or two sub-pixels with at least one of the adjacent pixels 22, pixel 23, pixel 24, pixel 25, pixel 26, and pixel 27 in order to form at least one multiplexed pixel different from the pixel 21, pixel 22, pixel 23, pixel 24, pixel 25, pixel 26, and pixel 27 of the display panel in the area where the pixel 21, pixel 22, pixel 23, pixel 24, pixel 25, pixel 26 and pixel 27 are located, i.e., rendering by using the principle of borrowing colors or sub-pixel rendering (SPR) technology so as to increase the resolution of the display panel, thereby improving the display effect of the display panel.

In some embodiments, shapes of the first sub-pixel 201, second sub-pixel 202 and third sub-pixel 203 are rectangle so as to increase the area arrangement percentage of the first sub-pixel 201, second sub-pixel 202 and third sub-pixel 203, which is conducive to further improving the display rate of the display panel.

In some embodiments, long edges of the first sub-pixel 201, second sub-pixel 202 and third sub-pixel 203 are equal, further increasing the area arrangement percentage of the first sub-pixel 201, second sub-pixel 202 and third sub-pixel 203, which is conducive to further improving the display rate of the display panel.

In other embodiments, long edges of each sub-pixel may not be equal. For example, if the size of the long edge of the first sub-pixel 201 among the first sub-pixel, second sub-pixel and third sub-pixel is D1, and the size of the long edges of the second sub-pixel 202 and the third sub-pixel 203 are D2 and D3, respectively, then D2 and D3 are between 0.8 D1 to 1.2 D1, which is able to increase the area arrangement percentage of the sub-pixels to a certain extent.

In some embodiments, the long edges of the first sub-pixel 201, second sub-pixel 202, and third sub-pixel 203 are parallel to the first direction, further increasing the area arrangement percentage of the first sub-pixel 201, second sub-pixel 202, and third sub-pixel 203, which is conducive to further improving the display rate of the display panel.

In some embodiments, the short edges of the first sub-pixel 201, second sub-pixel 202, and third sub-pixel 203 are parallel to the second direction, further increasing the area arrangement percentage of the first sub-pixel 201, second sub-pixel 202, and third sub-pixel 203, which is conducive to further improving the display rate of the display panel.

It is to be understood that in some other embodiments, the shape of each sub-pixel may also be other regular or irregular shapes, such as ellipses, polygons, and the specific settings of each edge may be set according to the corresponding requirements.

In some embodiments, the first sub-pixel 201, second sub-pixel 202 and third sub-pixel 203 are a red sub-pixel, a green sub-pixel and a blue sub-pixel, respectively.

In order to adapt to the lifespan of each color sub-pixel so that the display panel achieves a higher lifespan as much as possible, the area of the green sub-pixel is set to be greater than the area of the red sub-pixel, and the area of the blue sub-pixel is set to be greater than the area of the green sub-pixel. The area ratio of the green sub-pixel and the red sub-pixel is greater than 1 and less than or equal to 3, and the area ratio of the blue sub-pixel and the red sub-pixel is greater than 1.2 and less than or equal to 4. For example, the area ratio of the red sub-pixel, green sub-pixel, and blue sub-pixel may be 1:1.2:1.6, 1:1.3:1.8, 1:1.2:1.8, or 1:2.5:3.1.

In the case that the long edges of the first sub-pixel 201, second sub-pixel 202 and third sub-pixel 203 are equal, the short edges of each sub-pixel can be adjusted in order to adapt to the required areas of each sub-pixel. In some embodiments, the size of the short edges of the red sub-pixel, d1, is smaller than that of the short edges of the green sub-pixel, d2, and the size of the short edges of the green sub-pixel, d2, is smaller than that of the short edges of the blue sub-pixel, d3, to better adapt to the lifespan of each color sub-pixel so that the display panel achieves a higher lifespan as much as possible.

In some embodiments, the angle between the first direction and the second direction is an acute angle.

In some other embodiments, the angle between the first direction and the second direction may also be a right angle.

In some embodiments, in the first direction and the second direction, the same one or two sub-pixels are shared between the pixel and a plurality of adjacent pixels.

First, for sharing the same one sub-pixel, in the first direction and second direction, the same one sub-pixel is shared between the pixel and a plurality of adjacent pixels.

The specifics of the pixel arrangement in the display panel 2 are described below in conjunction with FIGS. 3 to 19. In some embodiments, the same shared sub-pixel herein is the first sub-pixel 201.

For example, please see in conjunction with FIG. 3, the pixel 21 shares this first sub-pixel 201 with all adjacent pixel 23, pixel 24 and pixel 25 that may share this first sub-pixel 201, so that in the area where the pixel 21, pixel 22, pixel 23, pixel 24, pixel 25, pixel 26 and pixel 27 are located, three multiplexed pixels 301, 302 and 303 may be additionally formed that are different from the pixel 21, pixel 22, pixel 23, pixel 24, pixel 25, pixel 26, and pixel 27.

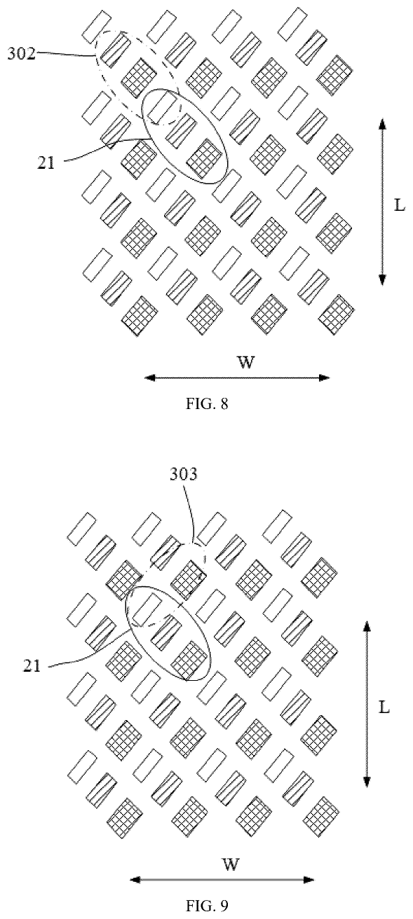

In other embodiments, the pixel 21 may also share the first sub-pixel with one of the adjacent pixel 23, pixel 24 and pixel 25, as shown in FIG. 8, 9 or 10, the pixel 21 shares a first sub-pixel 201 with the pixel 24, pixel 25 or pixel 23, so that, in the area where the pixel 21, pixel 22, pixel 23, pixel 24, pixel 25, pixel 26 and pixel 27 are located, one multiplexed pixel 302, 303 or 301 may be additionally formed that is different from the pixel 21, pixel 22, pixel 23, pixel 24, pixel 25, pixel 26 and pixel 27.

In other embodiments, the pixel 21 may share the first sub-pixel 201 with two of the adjacent pixel 23, pixel 24, and pixel 25, so that in the area where the pixel 21, pixel 22, pixel 23, pixel 24, pixel 25, pixel 26, and pixel 27 are located, two multiplexed pixels may be additionally formed that are different from the pixel 21, pixel 22, pixel 23, pixel 24, pixel 25, pixel 26, and pixel 27.

It will be appreciated that, in other embodiments, in at least one of the first direction and the second direction, the same sub-pixel shared among pixel 21 and other pixels is the second sub-pixel 202.

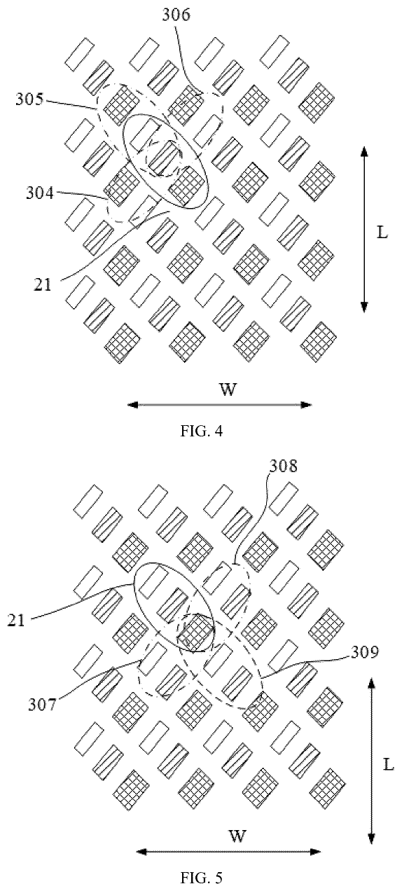

For example, as shown in FIG. 4, the pixel 21 shares the second sub-pixel 202 with adjacent pixel 22 and pixel 23, and shares this second sub-pixel 202 with adjacent pixel 25 and pixel 26, so that in the area where the pixel 21, pixel 22, pixel 23, pixel 24, pixel 25, pixel 26 and pixel 27 are located, two multiplexed pixels 304 and 306 which share second sub-pixel 202 are additionally formed that are different from the pixel 21, pixel 22, pixel 23, pixel 24, pixel 25, pixel 26, and pixel 27.

In other embodiments, the pixel 21 may also share the second sub-pixel 202 with adjacent pixel 22 and pixel 23, or may share this second sub-pixel 202 with adjacent pixel 25 and pixel 26, so that in the area where the pixel 21, pixel 22, pixel 23, pixel 24, pixel 25, pixel 26, and pixel 27 are located, one multiplexed pixel that shares the second sub-pixel 202 may be additionally formed that is different from the pixel 21, pixel 22, pixel 23, pixel 24, pixel 25, pixel 26, and pixel 27.

In yet further embodiments, in at least one of the first direction and the second direction, the same sub-pixel shared among the pixel 21 and other pixels is the third sub-pixel 203.

For example, as shown in FIG. 5, the pixel 21 shares the third sub-pixel 203 with all adjacent pixel 22, pixel 26 and pixel 27 that may share the third sub-pixel 203, so that in the area where pixel 21, pixel 22, pixel 23, pixel 24, pixel 25, pixel 26 and pixel 27 are located, three multiplexed pixels 307, 308 and 309 may be additionally formed that are different from the pixel 21, pixel 22, pixel 23, pixel 24, pixel 25, pixel 26 and pixel 27.

In other embodiments, the pixel 21 may also share the third sub-pixel 203 with one of the adjacent pixel 22, pixel 26, and pixel 27, so that in the area where the pixel 21, pixel 22, pixel 23, pixel 24, pixel 25, pixel 26, and pixel 27 are located, one multiplexed pixel may be additionally formed that is different from the pixel 21, pixel 22, pixel 23, pixel 24, pixel 25, pixel 26 and pixel 27.

In other embodiments, the pixel 21 may share the third sub-pixel 203 with two of the adjacent pixel 22, pixel 26, and pixel 27, so that in the area where the pixel 21, pixel 22, pixel 23, pixel 24, pixel 25, pixel 26, and pixel 27 are located, two multiplexed pixels may be additionally formed that are different from the pixel 21, pixel 22, pixel 23, pixel 24, pixel 25, pixel 26, and pixel 27 pixels.

Further, for cases that two sub-pixels of the pixel 21 are shared, in some embodiments, in at least one of the first direction and the second direction, the first pixel and the second pixel are shared between the pixel and at least one adjacent pixel.

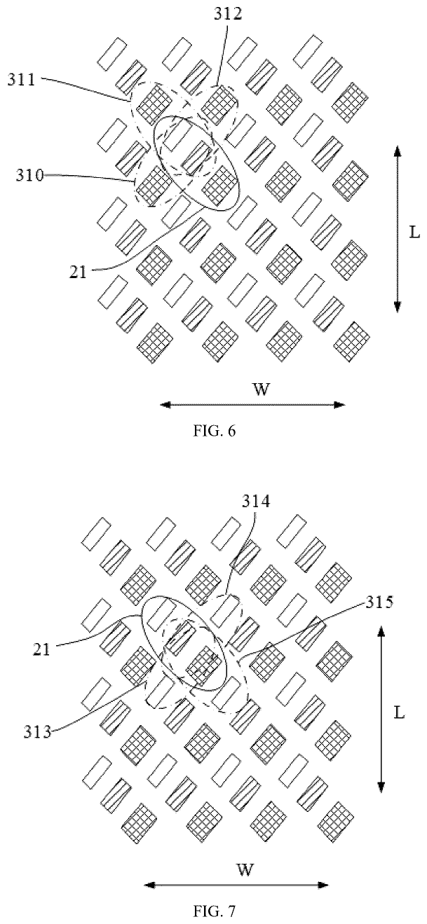

For example, as shown in FIG. 6, the pixel 21 shares the first sub-pixel 201 and the second sub-pixel 202 of the pixel 21 with all the adjacent pixel 23, pixel 24, and pixel 25 that may share the first sub-pixel 201 and the second sub-pixel 202, so that, in the area where the pixel 21, pixel 22, pixel 23, pixel 24, pixel 25, pixel 26, and pixel 27 are located, three multiplexed pixels 310, 311 and 312 may be additionally formed that are different from the pixel 21, pixel 22, pixel 23, pixel 24, pixel 25, pixel 26 and pixel 27.

In other embodiments, the pixel 21 may also share the first sub-pixel with one of the adjacent pixels 23, pixel 24, and pixel 25, as shown in FIG. 11, 12, or 13, the pixel 21 shares the first sub-pixel 201 and the second sub-pixel 202 with the pixel 24, pixel 25 or pixel 23, so that in the area where the pixel 21, pixel 22, pixel 23, pixel 24, pixel 25, pixel 26, and pixel 27 are located, one multiplexed pixel 311, 312, or 310 may be additionally formed that is different from the pixel 21, pixel 22, pixel 23, pixel 24, pixel 25, pixel 26, and pixel 27.

In other embodiments, the pixel 21 may share the first sub-pixel 201 and the second sub-pixel 202 with two of the adjacent pixel 23, pixel 24, and pixel 25, so that in the area where the pixel 21, pixel 22, pixel 23, pixel 24, pixel 25, pixel 26, and pixel 27 are located, two multiplexed pixels may be additionally formed that are different from the pixel 21, pixel 22, pixel 23, pixel 24, pixel 25, pixel 26 and pixel 27.

For cases that two sub-pixels of the pixel 21 are shared, in other embodiments, in at least one of the first direction and the second direction, the second sub-pixel and the third sub-pixel are shared between the pixel and at least one adjacent pixel.

For example, as shown in FIG. 7, the pixel 21 shares the second sub-pixel 202 and the third sub-pixel 203 of the pixel 21 with all the adjacent pixel 22, pixel 26, and pixel 27 that may share the second sub-pixel 202 and the third sub-pixel 203, so that, in the area where the pixel 21, pixel 22, pixel 23, pixel 24, pixel 25, pixel 26, and pixel 27 are located, three multiplexed pixels 313, 314 and 315 may be additionally formed that are different from the pixel 21, pixel 22, pixel 23, pixel 24, pixel 25, pixel 26 and pixel 27.

In other embodiments, the pixel 21 may also share the second sub-pixel 202 and the third sub-pixel 203 with one of the adjacent pixel 22, pixel 26, and pixel 27, so that in the area where the pixel 21, the pixel 22, the pixel 23, the pixel 24, the pixel 25, the pixel 26, and the pixel 27 are located, one multiplexed pixel may be additionally formed that is different from the pixel 21, pixel 22, pixel 23, pixel 24, pixel 25, pixel 26 and pixel 27.

In other embodiments, the pixel 21 may share the second sub-pixel 202 and the third sub-pixel 203 with two of the adjacent pixel 22, pixel 26, and pixel 27, so that in the area where the pixel 21, pixel 22, pixel 23, pixel 24, pixel 25, pixel 26, and pixel 27 are located, two multiplexed pixels may additionally be formed that are different from the pixel 21, pixel 22, pixel 23, pixel 24, pixel 25, pixel 26, and pixel 27.

In addition, for a pixel that shares one sub-pixel with an adjacent pixel, it may also share two sub-pixels with other pixels. For example, as shown in FIG. 4, the pixel 21 shares a second sub-pixel 202 with the adjacent pixel 22 and pixel 23, and shares this second sub-pixel 202 with the adjacent pixel 25 and pixel 26, while also sharing the first sub-pixel 201 and the second sub-pixel 202 with the adjacent pixel 24.

In other embodiments, a pixel may also share different sub-pixels with adjacent pixels of the pixel to form at least two multiplexed pixels. As shown in FIG. 20, the pixel 21 shares the first sub-pixel 201 with the adjacent pixel 24 to form a multiplexed pixel 302, and may also share the third sub-pixel with the pixel 26 to form a multiplexed pixel 317.

Furthermore, in other embodiments, a pixel may also share one sub-pixel with two adjacent pixels to form one multiplexed pixel, such as a multiplexed pixel 318 shown in FIG. 21.

The sub-pixels shared in the display panel can be set up according to certain rules in order to facilitate timing control and the like. For example, the shared pixels and the multiplexed pixels formed are similar in pixel area units of the same size. For example, as shown in FIGS. 14 to 17, the same multiplexing method is used in each pixel area unit involving two rows and two columns of pixels arranged along the length direction L and the width direction W, and the multiplexed pixels formed in each pixel area unit are arranged in a consistent manner.

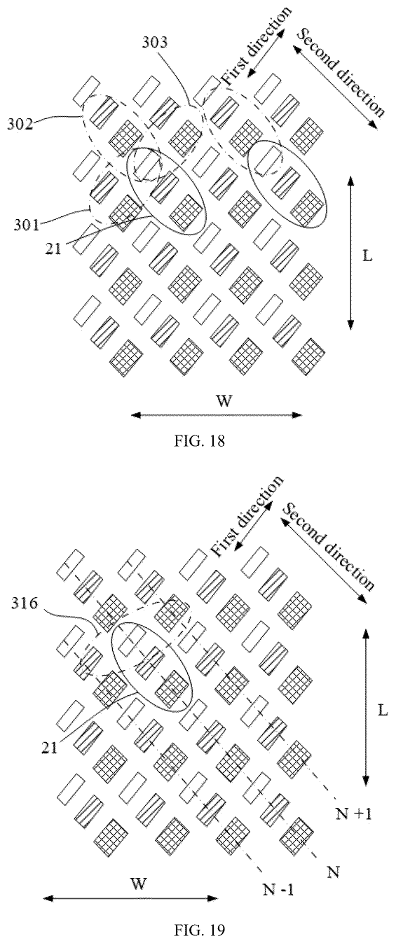

In other embodiments, for example, the shared pixels and the multiplexed pixels formed may not be similar in pixel area units of the same size. For example, as shown in FIG. 18, the same multiplexing method is used in each pixel area unit involving two rows and two columns of pixels arranged along the length direction L and the width direction W, and the multiplexed pixels formed in each pixel area unit are arranged in a different manner.

The foregoing are only preferred embodiments of the present disclosure, and do not constitute any formal limitation of the present disclosure. Although the present disclosure has been discussed in the preferred embodiments as described above, the preferred embodiments are not intended to limit the present disclosure. Any skilled person in the art may, within the scope of the technical solutions of the present disclosure, make slight changes or modifications to the above disclosure as the equivalent embodiments of the equivalent changes. Any simple changes, equivalent changes and modifications made based on the technical substance of the present disclosure and without departing from the technical solutions of the disclosure will still fall within the scope of the technical solutions of the present disclosure.

1. A display panel, comprising:
pixels arranged in an array, a row direction of the array being a first direction, each of the pixels comprising a first sub-pixel, a second sub-pixel and a third sub-pixel, the first sub-pixel, the second sub-pixel and the third sub-pixel being arranged in intervals along a second direction in sequence, wherein the first direction and the second direction have an angle therebetween, the angle being non-zero;
wherein a first pixel among the pixels and a second pixel among the pixels and neighboring the first pixel in the first direction or the second direction share one or two sub-pixels to form a multiplexed pixel, and
wherein an arrangement of the first sub-pixel, the second sub-pixel, and the third sub-pixel of the multiplexed pixel is different from an arrangement of the first sub-pixel, the second sub-pixel, and the third sub-pixel of the second pixel.

2. The display panel of claim 1, wherein
the first sub-pixel, the second sub-pixel and the third sub-pixel of the multiplexed pixel and the first sub-pixel, the second sub-pixel and the third sub-pixel of the first pixel are arranged in intervals in a row along the second direction, and
an arrangement order of the first sub-pixel, the second sub-pixel and the third sub-pixel of the multiplexed pixel is different from an arrangement order of the first sub-pixel, second sub-pixel and third sub-pixel of the first pixel.

3. The display panel of claim 1, wherein
the first sub-pixel, the second sub-pixel and the third sub-pixel of the multiplexed pixel are distributed in at least two rows in the first direction, and
the first sub-pixel, the second sub-pixel and the third sub-pixel of the first pixel are distributed in one row in the first direction.

4. The display panel of claim 3, wherein
the first sub-pixel, the second sub-pixel and the third sub-pixel of the first pixel are distributed in a N^{th} row in the first direction,
one or more shared sub-pixels of the multiplexed pixel are distributed in the N^{th} row in the first direction,
the first sub-pixel, the second sub-pixel and the third sub-pixel of the multiplexed pixel are distributed in at least the N^{th} row and a (N−1)^{th} row in the first direction or the first sub-pixel, the second sub-pixel and the third sub-pixel of the second-type multiplexed pixel are distributed in at least the N^{th} row and a (N+1)^{th} row in the first direction.

5. The display panel of claim 3, wherein the first sub-pixel, the second sub-pixel and the third sub-pixel of the multiplexed pixel are distributed in three rows in the first direction, respectively.

6. The display panel of claim 1, wherein at least one or two sub-pixels among the sub-pixels of the pixels are shared by four pixels among the pixels, with two pixels of the four pixels located in a row where the shared sub-pixels are located, and the other two pixels located in two rows on both sides of the shared sub-pixels, respectively.

7. The display panel of claim 1, wherein one sub-pixel is shared by the first pixel and the second pixel, the one sub-pixel is a first sub-pixel, a second sub-pixel or a third sub-pixel.

8. The display panel of claim 1, wherein two sub-pixels are shared by the first pixel and the second pixel, the two sub-pixels are a first sub-pixel and a second sub-pixel, or a second sub-pixel and a third sub-pixel.

9. The display panel of claim 1, wherein the first sub-pixel, the second sub-pixel and the third sub-pixel are a red sub-pixel, a green sub-pixel and a blue sub-pixel, respectively.

10. The display panel of claim 9, wherein an area ratio of the second sub-pixel to the first sub-pixel is greater than 1 and less than or equal to 3, and an area ratio of the third sub-pixel to the first sub-pixel is greater than 1.2 and less than or equal to 4.

11. The display panel of claim 1, wherein the first sub-pixel, the second sub-pixel and the third sub-pixel are rectangular, elliptical or polygonal.

12. The display panel of claim 11, wherein the first sub-pixel, the second sub-pixel and the third sub-pixel are rectangular, and one of the first sub-pixel, second sub-pixel and third sub-pixel has long edges D1, and the other two sub-pixels have long edges D2, D3, both D2 and D3 being between 0.8 D1 to 1.2 D1.

13. The display panel of claim 12, wherein the long edges of the first sub-pixel, the second sub-pixel and the third sub-pixel are equal.

14. The display panel of claim 12, wherein the long edges of the first sub-pixel, the second sub-pixel and the third sub-pixel are parallel to the first direction.

15. The display panel of claim 12, wherein short edges of the first sub-pixel, the second sub-pixel and the third sub-pixel are parallel to the second direction.

16. The display panel of claim 1, wherein the angle between the first direction and the second direction is an acute or right angle; and
wherein the display panel has scanning lines and data lines arranged in a crisscrossed manner, and the first direction and a direction in which the scanning lines extend have an angle therebetween, the angle being an acute angle.

17. A display device comprising the display panel of claim 1.

18. The display device of claim 17, wherein
the first sub-pixel, the second sub-pixel and the third sub-pixel of the multiplexed pixel and the first sub-pixel, the second sub-pixel and the third sub-pixel of the first pixel are arranged in intervals in a row along the second direction, and
an arrangement order of the first sub-pixel, the second sub-pixel and the third sub-pixel of the multiplexed pixel is different from an arrangement order of the first sub-pixel, second sub-pixel and third sub-pixel of one of the first pixel.

19. The display device of claim 17, wherein
the first sub-pixel, the second sub-pixel and the third sub-pixel of the multiplexed pixel are distributed in at least two rows in the first direction, and
the first sub-pixel, the second sub-pixel and the third sub-pixel of the first pixel are distributed in one row in the first direction.

20. The display panel of claim 4, wherein the first sub-pixel, the second sub-pixel and the third sub-pixel of the multiplexed pixel are distributed in three rows in the first direction, respectively.
